(19) United States
(12) Patent Application Publication
(10) Pub. No.: US 2002/0137323 A1
(43) Pub. Date: Sep. 26, 2002

(54) Metal ion diffusion barrier layers

(76) Inventor: Mark Jon Loboda, Bay City, MI (US)

Correspondence Address: DOW CORNING CORPORATION, INTELLECTUAL PROPERTY DEPT. -MAIL CO1232, 2200 W. SALZBURG ROAD, P.O. BOX 994, MIDLAND, MI, 48686-0994, US

(21) Appl. No.: 10/037,289

(22) Filed: Jan. 3, 2002

Related U.S. Application Data
(60) Provisional application No. 60/259,489, filed on Jan. 3, 2001.

(51) Int. Cl. H01L 21/44

(52) U.S. Cl. 438/600

(57) ABSTRACT

An integrated circuit comprising a subassembly of solid state devices formed into a substrate made of a semiconducting material. The devices within the subassembly are connected by metal wiring formed from conductive metals. A diffusion barrier layer of an alloy film having the composition of Si_{w}CₓO_{y}H_{z} where w has a value of 10 to 33, preferably 18 to 20 atomic %, x has a value of 1 to 66, preferably 18 to 21 atomic percent, y has a value of 1 to 66, preferably 5 to 38 atomic % and z has a value of 0.1 to 60, preferably 25 to 32 atomic %; and w+x+y+z=100 atomic % is formed on at least the metal wiring.

This application claims the benefit of U.S. Provisional Application No. 60/259,489 filed Jan. 3, 2001.

### BACKGROUND OF THE INVENTION

Traditionally, materials such as amorphous hydrogenated silicon nitride (a-SiN:H) and amorphous hydrogenated silicon carbide (a-SiC:H) have been implemented in the contact or intermetal dielectric isolation technology used in semiconductor integrated circuit (IC) fabrication to prevent thermal or electrical field driven diffusion of interconnection metal within the device. Diffusion of the metal within the IC results in premature failure of the device. The use of these materials has been based on the known properties of common electrical isolation dielectrics such as SiO₂ and similar oxide based related materials to behave as poor barriers. With the industry requirement to minimize the electrical resistance-capacitance (RC) delay associated with the circuit interconnections, the aforementioned carbides and nitrides has been challenged as these materials have equal to or higher dielectric permittivity than SiO₂, and result in increased interconnection capacitance.

This invention relates to the use of a low permittivity material, an alloy film having the composition of Si_{w}CₓO_{y}H_{z}, as an effective barrier against the diffusion of metal ions such as Cu, Al, etc. in multilevel metal integrated circuit and wiring board designs. The function of the Si_{w}CₓO_{y}H_{z} film is to stop the migration of metal ions between adjacent conductors that are the device interconnections in the electrical circuit. The reliability added to the circuit by the Si_{w}CₓO_{y}H_{z} film allows the use of low resistance conductors and low dielectric constant materials as insulation media between the conductors.

### SUMMARY OF THE INVENTION

The present invention relates to an improved integrated circuit having greater speed of operation and reliability. The circuit comprises a subassembly of solid state devices formed into a substrate made of a semiconducting material. The devices within the subassembly are connected by metal wiring formed from conductive metals. A diffusion barrier layer of an alloy film having the composition of Si_{w}CₓO_{y}H_{z} where w has a value of 10 to 33, preferably 18 to 20 atomic %, x has a value of 1 to 66, preferably 18 to 21 atomic percent, y has a value of 1 to 66, preferably 5 to 3 8 atomic % and z has a value of 0.1 to 60, preferably 25 to 32 atomic %; and w+x+y+z=100 atomic % is in contact with the metal wiring.

### BRIEF DESCRIPTION OF THE DRAWINGS

FIG. 1 is a cross-section of a device formed using subtractive technology.

FIG. 2 is a cross-section of a device formed using damascene technology.

### DETAILED DESCRIPTION

This invention pertains to the use of alloy film having the composition of Si_{w}CₓO_{y}H_{z} (“Si_{w}CₓO_{y}H_{z} film”) where w has a value of 10 to 33, preferably 18 to 20 atomic %, x has a value of 1 to 66, preferably 18 to 21 atomic percent, y has a value of 1 to 66, preferably 5 to 38 atomic % and z has a value of 0.1 to 60, preferably 25 to 32 atomic %; and w+x+y+z=100 atomic %. The Si_{w}CₓO_{y}H_{z} film is used to stop the migration of metal atoms between adjacent device interconnections in an electrical circuit. The Si_{w}CₓO_{y}H_{z} film also has a lower dielectric permittivity than amorphous hydrogenated silicon nitrides (a-SiN:H) and amorphous hydrogenated silicon carbides (a-SiC:H). The dielectric permittivity of the Si_{w}CₓO_{y}H_{z} film can be more than 50% lower than these nitrides and carbides. This lower dielectric permittivity helps to reduce the capacitance associated with the interconnections. The Si_{w}CₓO_{y}H_{z} film also has a lower permittivity than SiO₂ films. Therefore, in addition to preventing metal diffusion, the material is a suitable interdielectric itself. As a multifunctional material, the implementation of the Si_{w}CₓO_{y}H_{z} film simplifies IC fabrication by eliminating the need for multiple interlayer materials in an intermetal isolation scheme, and thus reduces IC manufacturing costs. Since the Si_{w}CₓO_{y}H_{z} film material is a barrier against metal diffusion, the need for the metal-based diffusion barriers used adjacent to the conductor metal itself is eliminated, further simplifying fabrication and reducing costs. An example would be the elimination of Ti or Ta based layers adjacent to the copper conductors. Finally, these Ti and Ta based layers also present limits to the lowest resistivity attainable in a metal interconnection, and their elimination creates the opportunity to reduce interconnection resistivity. Thus it can be claimed that the implementation of the Si_{w}CₓO_{y}H_{z} film allows the manufacture of extremely low RC delay interconnections by eliminating the need for high permittivity dielectric films and high resistivity metal-based barrier metals. This will result in an improvement in the overall performance of high speed integrated circuits.

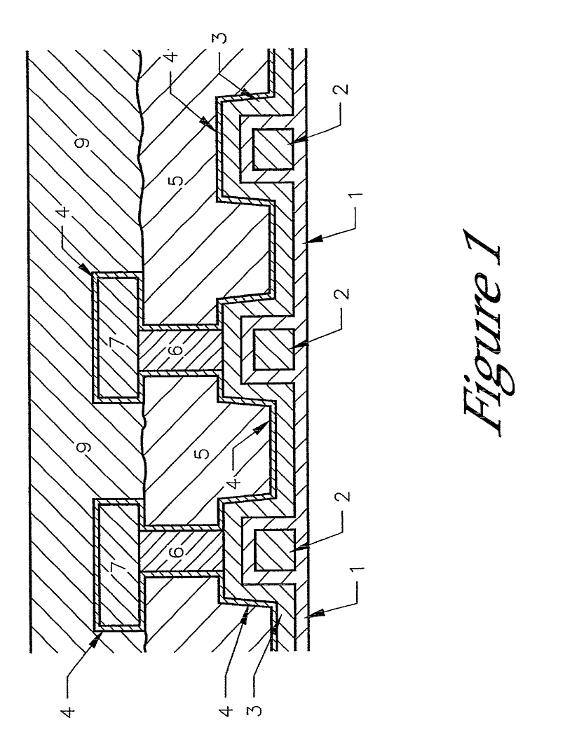

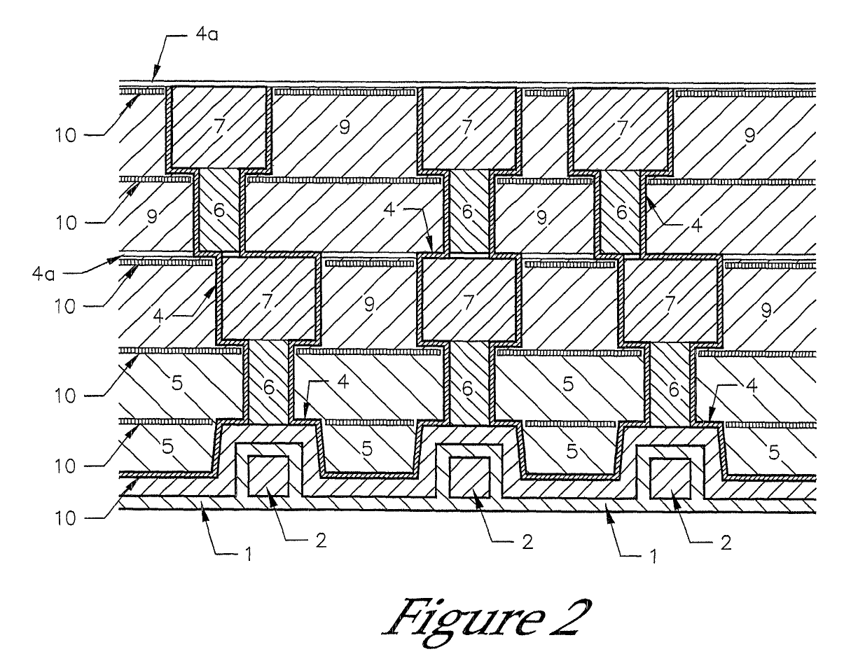

The integrated circuit subassemblies used in the process of this invention are not critical and nearly any which are known in the art and/or produced commercially are useful herein. FIG. 1 represents a circuit assembly produced by subtractive technology. When subtractive technology is used a layer of wiring is produced and then the wiring is covered with the interlayer materials. FIG. 2 represents a circuit assembly produced using damascene technology. When damascene technology is used, the wiring is applied into trenches after the interlayer dielectrics are deposited and the trenches used to isolate the wiring have been formed.

The processes used to produce such circuits are also known and not critical to the invention. Exemplary of such circuits are those comprising a semiconductor substrate (eg., silicon, gallium arsenide, etc.) having an epitaxial layer grown thereon. This epitaxial layer is appropriately doped to form the PN-junction regions which constitute the active, solid state device regions of the circuit. These active, device regions are diodes and transistors which form the integrated circuit when appropriately interconnected by metal wiring layers. FIG. 1 depicts such a circuit subassembly (1) having device regions (2) and thin film metal wiring (3) interconnecting the devices. FIG. 2 depicts an alternate circuit assembly (1) having device regions (2) and thin film wiring (3) interconnecting the devices. This invention is not intended to be limited to the application of the Si_{w}CₓO_{y}H_{z} film in these two structures. Alternative structures where the Si_{w}CₓO_{y}H_{z} film provides a barrier against metal ion diffusion in the integrated circuit may also be used herein.

The material used for the metal wiring layer is not limited so long as it is a conductive metal. The metal wiring layers on integrated circuit subassemblies are generally thin films of aluminum or copper. Additionally, the metal wiring layers can be silver, gold, alloys, superconductors and other.

Methods for depositing the metal layers are known in the art. The specific method utilized is not critical. Examples of such processes include various physical vapor deposition (PVD) techniques such as sputtering and electron beam evaporation.

A Si_{w}CₓO_{y}H_{z} film is formed such that it contacts the metal wiring layer and protects those regions where metal ions can diffuse within the device. When the device is formed using subtractive technology, the Si_{w}CₓO_{y}H_{z} film is applied over the wiring after the application of the wiring on the device but before the application of any other interlayers. When the device is formed using damascene technology, the Si_{w}CₓO_{y}H_{z} film is applied in the trenches before the formation of the interconnect and metal wiring. A Si_{w}CₓO_{y}H_{z} film may then be applied over any remaining exposed surfaces of the metal wiring. Alternatively the Si_{w}CₓO_{y}H_{z} film may be applied under the metal wiring layer, for example as exemplified by layer (4) in FIGS. 1 and. 2. Alternatively, it is contemplated that one could selectively apply the Si_{w}CₓO_{y}H_{z} film on just the wiring by, for example, masking or one could coat the entire surface and then etch away those areas where the Si_{w}CₓO_{y}H_{z} film was not desired. The Si_{w}CₓO_{y}H_{z} film can be used in conjunction with known diffusion barrier materials. For example, the wiring may be partially covered with a traditional barrier metal and then the remaining wiring may be covered with the Si_{w}CₓO_{y}H_{z} film.

Methods of applying Si_{w}CₓO_{y}H_{z} film are not critical to the invention and many are known in the art. Examples of applicable methods include a variety of chemical vapor deposition techniques such as conventional CVD, photochemical vapor deposition, plasma enhanced chemical vapor deposition (PECVD), electron cyclotron resonance (ECR), jet vapor deposition, etc. and a variety of physical vapor deposition techniques such as sputtering, electron beam evaporation, etc. These processes involve either the addition of energy (in the form of heat, plasma, etc.) to a vaporized species to cause the desired reaction or the focusing of energy on a solid sample of the material to cause its deposition.

Preferably the Si_{w}CₓO_{y}H_{z} film is applied by the method disclosed in U.S. patent application Ser. No. 09/086,811, filed May 29, 1998, and assigned to Dow Corning Corporation, herein incorporated by reference for its teaching of how to form Si_{w}CₓO_{y}H_{z} films. According to this method, the Si_{w}CₓO_{y}H_{z} films are produced from a reactive gas mixture comprising a methyl-containing silane and an oxygen providing gas. Methyl-containing silanes that may be used include methylsilane (CH₃SiH₃), dimethylsilane ((CH₃)₂SiH₂), trimethylsilane ((CH₃)₃SiH) and tetramethylsilane ((CH₃)₄Si), preferably trimethylsilane. A controlled amount of oxygen is present in the deposition chamber. The oxygen may be controlled by the type of oxygen providing gas used, or by the amount of oxygen providing gas that is used. If too much oxygen is present in the deposition chamber a silicon oxide film with a stoichiometry close to SiO₂ will be produced. If not enough oxygen is present in the deposition chamber a silicon carbide film with a stoichiometry close to SiC will be produced. Under either of these scenarios the desired properties in the film will not be achieved. Oxygen providing gases include, but are not limited to air, ozone, oxygen, nitrous oxide and nitric oxide, preferably nitrous oxide. The amount of oxygen providing gas is typically less than 5 volume parts oxygen providing gas per volume part of methyl-containing silane, more preferably from 0.1 to 4.5 volume parts of oxygen providing gas per volume part of methyl-containing silane. One skilled in the art will be able to readily determine the amount of oxygen providing gas based on the type of oxygen providing gas and the deposition conditions to produce a film have a composition of Si_{w}CₓO_{y}H_{z} where w has a value of 10 to 33, preferably 18 to 20 atomic %, x has a value of 1 to 66, preferably 18 to 21 atomic percent, y has a value of 1 to 66, preferably 5 to 38 atomic % and z has a value of 0.1 to 60, preferably 25 to 32 atomic %; and w+x+y+z=100 atomic %

In conventional chemical vapor deposition, the coating is deposited by passing a stream of the desired precursor gases over a heated substrate. When the precursor gases contact the hot surface, they react and deposit the coating. Substrate temperatures in the range of about 100-1000° C. are sufficient to form these coatings in several minutes to several hours, depending on the precursors and the thickness of the coating desired. If desired, reactive metals can be used in such a process to facilitate deposition.

In PECVD, the desired precursor gases are reacted by passing them through a plasma field. The reactive species thereby formed are then focused at the substrate where they readily adhere. Generally, the advantage of this process over CVD is that lower substrate temperature can be used. For instance, substrate temperatures of about 50° C. up to about 600° C. are functional.

The plasma used in such processes can comprise energy derived from a variety of sources such as electric discharges, electromagnetic fields in the radio-frequency or microwave range, lasers or particle beams. Generally preferred in most plasma deposition processes is the use of radio frequency (10 kHz-102 MHz) or microwave (0.1-10 GHz) energy at moderate power densities (0.1-5 watts/cm2). The specific frequency, power and pressure, however, are generally tailored to the precursor gases and the equipment used.

Other precursors known in the art for forming Si_{w}CₓO_{y}H_{z} films may be used herein. The precursor may be a single compound that provides the Si, C, O, and H elements or the precursor, for example, a methyl silicone. Or the precursor can be a mixture of compounds to provide the Si, C, O and H elements, for example, silane, a source of oxygen (i.e O₂, O₃, H₂O₂, N₂O, etc.) and an organic compound (i.e. methane); or a methyl-containing silane and a source of oxygen as described above. The preferred method for forming the Si_{w}CₓO_{y}H_{z} film is the plasma enhanced chemical vapor deposition of trimethylsilane with N₂O.

The films used herein can also be produced by application of liquid precursors by spin-on or other liquid depositions techniques. Organosiloxanes and silsesquioxanes which are then cured after application can be used to produced the forming Si_{w}CₓO_{y}H_{z} films.

The films used herein have the can be represented by the formula Si_{w}CₓO_{y}H_{z} where w has a value of 10 to 33, preferably 18 to 20 atomic %, x has a value of 1 to 66, preferably 18 to 21 atomic percent, y has a value of 1 to 66, preferably 31 to 38 atomic % and z has a value of 0.1 to 60, preferably 25 to 32 atomic %; and w+x+y+z=100 atomic %. Other elements, such as fluorine (F), can be introduced into the film so long as these elements do not change the diffusion barrier properties of the film.

The devices formed herein are typically multilayer devices, however, the Si_{w}CₓO_{y}H_{z} films can be used in single layer devices. Other materials such as traditional dielectric materials may be applied on top of the Si_{w}CₓO_{y}H_{z} film. FIG. 1 shows such a second metal wiring layer (7) which is interconnected with selected regions of the first layer of wiring by interconnects (6). Again, however, a Si_{w}CₓO_{y}H_{z} film should be deposited between the dielectric and the metal to prevent diffusion of the metal into the dielectric. This Si_{w}CₓO_{y}H_{z} film can be formed as described above. In such a manner, the metal wiring is sandwiched between Si_{w}CₓO_{y}H_{z} films. This process can be repeated many times for the various layers of metallization within a circuit.

It should also be noted that this technology can be applied to the wiring boards onto which the above circuits are mounted. The structure of the metal wiring and Si_{w}CₓO_{y}H_{z} films on these wiring boards would be the same as that described above. Additional uses include covering metals where diffusion of the metal into another layer would be undesirable.

In FIGS. 1 and 2 the layers can be described as follows:

1 is the circuit assembly. This can be any circuit assembly known in the art.

2 is the device regions. Device regions are known in the art and summarized herein above.

3 is a first metal wiring layer. Methods for forming metal wiring are known in the art and summarized herein, above. The metal wiring (3) is formed from a conductive metal as described previously herein.

4 is a barrier. The barrier (4) may be a Si_{w}CₓO_{y}H_{z} film or a combination of the Si_{w}CₓO_{y}H_{z} film with one or more barrier materials such as a-SiC:H, a-SiN:H, a-SiCN:H, barrier metals (i.e. Ta, Ti) and other known barrier materials. Typically, when a combination of barrier materials is used, the materials cover different parts of the wiring. Preferably the barrier layer is a Si_{w}CₓO_{y}H_{z} film as described herein. Preferably layer 4 is produced by the plasma enhanced chemical vapor deposition of trimethylsilane with N₂O.

4(a) is also a barrier layer as described herein. 4(a) is represented in FIG. 2 only.

5 is a first interlayer dielectric. The interlayer dielectric can be produced from any known interlayer material such as silicon oxides, silicon carbide, silicon oxycarbides, silicon nitrides, silicon oxynitrides, silicon carbonitirides, organic materials such as polyimide, epoxy, PARYLENE™, SiLK®, those produced from hydrogen silsesquioxane (FOx®, XLK™). Additionally, the interlayer dielectric can be the Si_{w}CₓO_{y}H_{z} film described herein as the barrier layer. This is one of the unique features of using Si_{w}CₓO_{y}H_{z} film. The Si_{w}CₓO_{y}H_{z} film when applied in thicknesses sufficient to at least partially fill in the gaps of between the metal wiring can also function as the dielectric material. This is due to the low dielectric constant and low resistivity of this material.

6 is the interconnect. The interconnect (6) connects a first layer of metal wiring with a second layer metal wiring. The interconnect (6) may be formed from the same or different conductive metal as used in the metal wiring.

7 is a second layer of metal wiring. This second metal wiring (7) may be made from the same or different conductive metal as the first metal wiring layer.

9 is a second interlayer dielectric. The second interlayer dielectric (9) can be the same or different from the first interlayer dielectric (5)

10 is an etch stop (FIG. 2). This layer is applied to prevent the etching down into other layers when forming the trenches in which to apply the metal wiring in a device formed by the damascene technology.

This invention is not intended to be limited to devices having these layers only. Additional layers that affect the planarazation, passiviation, protection or operation of the device may be formed in or on the devices.

### EXAMPLES

The following non-limiting examples are provided so that one skilled in the art may more readily understand the invention.

The following examples demonstrate the deposition of an oxidized organosilane thin film having excellent diffusion barrier properties and low k value. These examples were undertaken using a chemical vapor deposition chamber, “DxZ” which included a solid state RF matching unit with, and a chamber process kit manufactured by Applied Materials, Inc.

### Example 1

An oxidized trimethylsilane film was deposited on an 8-inch silicon wafer at a chamber pressure of 8.7 Torr and temperature of 370° C. from which reactive gases were flown into the reactor as follows:

| | |
|---|---|
| Trimethylsilane, (CH₃)₃SiH, at | 210 sccm |
| Helium, He, at | 600 sccm |
| Carbon Dioxide, CO₂, at | 165 sccm |

The substrate was positioned 435 mils from the gas distribution showerhead and 585 W of high frequency power (13.56 MHz) was applied to the showerhead for plasma-enhanced deposition. The oxidized trimethylsilane material had a refractive index of 1.88, was deposited at a rate of 1467 A/min with across wafer uniformity of 2%, and had dielectric constant of 4.5.

### EXAMPLE 2

An oxidized trimethylsilane film was deposited on an 8-inch silicon wafer at a chamber pressure of 7 Torr and a temperature of 370° C. from which reactive gases were flown into the reactor as follows:

| | |
|---|---|
| Trimethylsilane, (CH₃)₃SiH, at | 350 sccm |
| Helium, He, at | 300 sccm |
| Nitrous Oxide, N₂O, at | 420 sccm |

The substrate was positioned 300 mils from the gas distribution showerhead and 800 W of high-frequency power (13.56 MHz) was applied to the showerhead for plasma-enhanced deposition. The oxidized trimethylsilane material had a refractive index of 1.46, was deposited at a rate of 14080 A/min with across wafer uniformity of 3%, and had dielectric constant of 2.6.

### EXAMPLE 3

An oxidized trimethylsilane film was deposited on an 8-inch silicon wafers at a chamber pressure of 6 Torr and a temperature of 370° C. from which reactive gases were flown into the reactor as follows:

| | |
|---|---|
| Trimethylsilane, (CH₃)₃SiH, at | 350 sccm |
| Helium, He, at | 300 sccm |
| Nitrous Oxide, N₂O, at | 820 sccm |

The substrate was positioned 400 mils from the gas distribution showerhead and 625 W of high-frequency power (13.56 MHz) plus 95 W of low-frequency power (350 KHz) was applied to the showerhead for plasma-enhanced deposition. The oxidized Trimethylsilane material had a refractive index of 1.44, was deposited at a rate of 16438 A/min with across wafer uniformity of 5%, and had dielectric constant of 2.5.

### EXAMPLE 4

An oxidized trimethylsilane film was deposited on an 8-inch silicon wafer at a chamber pressure of 8.7 Torr and a temperature of 370° C. from which reactive gases were flown into the reactor as follows:

| | |
|---|---|
| Trimethylsilane, (CH₃)₃SiH, at | 210 sccm |
| Helium, He, at | 600 sccm |
| Oxygen, O2, at | 100 sccm |

The substrate was positioned 435 mils from the gas distribution showerhead and 700 W of high-frequency power (13.56 MHz) was applied to the showerhead for plasma-enhanced deposition. The oxidized trimethylsilane material had a refractive index of 1.41, was deposited at a rate of 5965 A/min with across wafer uniformity of 4%, and had a dielectric constant of 2.6.

### EXAMPLE 5

An oxidized trimethylsilane film was deposited on an 8-inch silicon wafer at a chamber pressure of 8.7 Torr and a temperature of 370° C. from which reactive gases were flown into the reactor as follows:

| | |
|---|---|
| Trimethylsilane, (CH₃)₃SiH, at | 200 sccm |
| Helium, He, at | 800 sccm |
| Nitrous Oxide, N₂O at | 100 sccm |
| Nitrogen, N₂ at | 200 sccm |

The substrate was positioned 435 mils from the gas distribution showerhead and 585 W of high-frequency power (13.56 MHz) was applied to the showerhead for plasma-enhanced deposition. The oxidized trimethylsilane material had a refractive index of 1.59, was deposited at a rate of 2058 A/min with across wafer uniformity of 6.5%, and had a dielectric constant of 3.4.

### EXAMPLE 6

An oxidized trimethylsilane film was deposited on an 8-inch silicon wafer at a chamber pressure of 8.7 Torr and a temperature of 37° C. from which reactive gases were flown into the reactor as follows:

| | |
|---|---|
| Trimethylsilane, (CH₃)₃SiH, at | 200 sccm |
| Helium, He, at | 800 sccm |
| Nitrous Oxide, N₂O at | 150 sccm |
| Nitrogen, N₂ at | 100 sccm |

The substrate was positioned 435 mils from the gas distribution showerhead and 585 W of high-frequency power (13.56 MHz) was applied to the showerhead for plasma-enhanced deposition. The oxidized trimethylsilane material had a refractive index of 1.48, was deposited at a rate of 5410 A/min with across wafer uniformity of 5%, and had a dielectric constant of 3.0.

### EXAMPLE 7

SiCH films were deposited with and without the addition of small amounts of N₂O in the gas mixture of the Applied Materials PECVD tool. Table 1 summarizes the deposition parameters.

| | deposition | | Press | (CH₃)₃SiH | He | N₂O | |
|---|---|---|---|---|---|---|---|
| Run ID | time (s) | RF (W) | (T) | (sccm) | (sccm) | (sccm) | k |
| 7-1 | 46.0 | 585 | 8.7 | 210 | 600 | 0 | 4.6 |
| 7-2 | 39.2 | 585 | 8.7 | 210 | 600 | 61 | 3.8 |
| 7-3 | 39.2 | 585 | 8.7 | 210 | 600 | 81 | 3.5 |
| 7-4 | 39.2 | 585 | 8.7 | 210 | 600 | 101 | 3.4 |
| 7-5 | 46.0 | 585 | 8.7 | 210 | 600 | 0 | 5.1 |
| 7-6 | 28 | 585 | 8.7 | 210 | 600 | 101 | 3.9 |

Dielectric constant, k, was measured using capacitor structures formed with Cu electrodes, and the results at 1 MHz are shown in the table. The incorporation of more N₂O slightly lowers the relative permittivity, k.

Measurements of the dielectric breakdown strength at room temperature show that processes which include N₂O deposit films which exhibit higher breakdown strength, in the range of 4-5 MV/cm, as opposed to those without N₂O (e.g. a-SiC:H) which are about 3.0 MV/cm. In another test of these materials, the bias-temperature-stress test for copper diffusion, a high electric field (2.5 MV/cm) is applied to the capacitor while it is held at 250° C. The application of a positive voltage to the electrode will try force the Cu in the electrode through the capacitor to the opposite electrode. When this occurs the capacitor will become conductive and a short circuit will occur. The barrier property is assessed by the time it takes to reach the short circuit condition. It is found that the time to create capacitor failure in films deposited without N₂O (e.g. a-SiC:H) is around 30000-80000 sec, and is 10-100× lower than that measured on films deposited with N₂O. Therefore the introduction of the oxidant also improves the barrier properties.

What is claimed is:

1. An integrated circuit comprised of a subassembly of solid state devices formed into a substrate made of semiconducting material, metal wiring connecting the solid state devices, and a diffusion barrier layer formed on at least the metal wiring wherein said diffusion barrier layer is an alloy film having the composition Si_{w}CₓO_{y}H_{z} where w has a value of 10 to 33, x has a value of 1 to 66, y has a value of 1 to 66, z has a value of 0.1 to 60, and w+x+y+z=100 atomic %.

2. The integrated circuit as claimed in claim 1 wherein the diffusion barrier layer is produced by chemical vapor deposition.

3. The integrated circuit as claimed in claim 1 wherein the diffusion barrier layer is produced by spin-on deposition.

4. The integrated circuit as claimed in claim 2 wherein the diffusion barrier layer is produced by chemical vapor deposition of a reactive gas mixture comprising a methyl-containing silane and a controlled amount of an oxygen providing gas.

5. The integrated circuit as claimed in claim 4 wherein the methyl-containing silane is trimethylsilane.

6. The integrated circuit as claimed in claim 4 wherein the oxygen providing gas is selected from CO₂, CO, ozone, oxygen, nitrous oxide and nitric oxide.

7. The integrated circuit as claimed in claim 1 wherein w has a value of 18 to 20 atomic %.

8. The integrated circuit as claimed in claim 1 wherein x has a value of 18 to 21 atomic %.

9. The integrated circuit as claimed in claim 1 wherein y has a value 5 to 38 atomic %.

10. The integrated circuit as claimed in claim 1 wherein z has a value of 25 to 32 atomic %.

11. The integrated circuit as claimed in claim 1 wherein the metal wiring is aluminum.

12. The integrated circuit as claimed in claim 1 wherein the metal wiring is copper.

13. A method of preventing migration of metal ions between adjacent device interconnections in an electrical circuit having metal wiring by applying over at least the metal wiring a diffusion barrier layer of an alloy film having the composition Si_{w}CₓO_{y}H_{z} where w has a value of 10 to 33, x has a value of 1 to 66, y has a value of 1 to 66, z has a value of 0.1 to 60, and w+x+y+z=100 atomic %.

14. The method as claimed in claim 13 wherein the diffusion barrier layer is produced by chemical vapor deposition.

15. The method as claimed in claim 14 wherein the diffusion barrier layer is produced by chemical vapor deposition of a reactive gas mixture comprising a methyl-containing silane and a controlled amount of an oxygen providing gas.

16. The method as claimed in claim 15 wherein the methyl-containing silane is trimethylsilane.

17. The method as claimed in claim 16 wherein the oxygen providing gas is selected from air, ozone, oxygen, nitrous oxide and nitric oxide.

18. The method as claimed in claim 17 wherein w has a value of 18 to 20 atomic %.

19. The method as claimed in claim 18 wherein x has a value of 18 to 21 atomic %.

20. The method as claimed in claim 19 wherein y has a value 31 to 38 atomic %.

21. The method as claimed in claim 20 wherein z has a value of 25 to 32 atomic %.

22. The method as claimed in claim 21 wherein the metal wiring is aluminum.

23. The method as claimed in claim 22 wherein the metal wiring is copper.
